(19) United States
(12) Patent Application Publication
(10) Pub. No.: US 2005/0092981 A1
(43) Pub. Date: May 5, 2005

(54) Superconducting integrated circuit and methods of forming same

(76) Inventor: Jeffrey H. Hunt, Chatsworth, CA (US)

Correspondence Address: INGRASSIA FISHER & LORENZ, P.C., 7150 E. CAMELBACK, STE. 325, SCOTTSDALE, AZ, 85251, US

(21) Appl. No.: 10/701,773

(22) Filed: Nov. 4, 2003

(51) Int. Cl. H01L 29/08

(52) U.S. Cl. 257/31; 257/32; 257/34

(57) ABSTRACT

An integrated circuit formed on a substrate suitably includes a number of superconducting junctions. Each superconducting junction includes a first superconducting material disposed upon the substrate, an insulating material formed on the first superconducting material, and a second superconducting material formed on the insulating material to create a Josephson junction. The second superconducting material is a different material from the first superconducting material to aid in manufacturability. Any number of electrically conductive interconnects are also provided to interlink the superconducting junctions to thereby form the integrated circuit. Examples of superconducting materials that may be used for the various layers include YBaCu₃O_{7-y} (YBCO) and Bi₂Sr₂CaCu₂O_{y} (Bi2212). Various circuits and techniques relating to superconducting devices are also described.

### TECHNICAL FIELD

The present invention generally relates to superconducting devices, and more particularly relates to an integrated circuit including superconducting devices.

### BACKGROUND

When electricity flows in a conventional conducting material (e.g. copper wire), some energy is inevitably lost due to heat dissipation. Superconductors, however, are materials that conduct electricity without appreciable loss of energy when the material is cooled below a critical temperature (T_{c}). Critical temperatures vary among superconducting materials, but are typically on the order of 50-130 degrees Kelvin, or the approximate temperature of liquid helium or nitrogen. Because no heat is produced as electrons pass through the complex lattice structure of a superconducting material, superconductors are able to transfer electricity with no significant current loss during transmission.

In addition to conducting electricity very efficiently, superconductors have been known to produce “tunneling currents” when two superconducting layers are separated by a thin insulating or conducting layer. This phenomenon is referred to as the “Direct Current (DC) Josephson Effect”, and is contrary to behavior expected from ordinary materials in which an electric potential difference (e.g. voltage) must be present to induce electric current. Josephson arrangements of superconducting materials have also been observed to produce alternating currents (AC) when a DC voltage is applied across the superconducting layers, a phenomenon referred to as the “AC Josephson Effect”. Josephson currents are believed to result from the quantum mechanical wave nature of the electron, and Josephson junctions are becoming more frequently used in very high speed switching circuits as well as in highly sensitive magnetometers, superconducting quantum interference devices (SQUIDs) and the like.

Although many have attempted to exploit Josephson currents in various devices and circuits, the specialized nature of most superconducting materials has limited wide-scale adoption, particularly within integrated circuits such as computer chips. In particular, conventional Josephson devices are formed from two identical layers of superconducting material, which can be very difficult to process with conventional manufacturing techniques. Photolithography used in semiconductor fabrication, for example, can be very difficult to apply to superconducting chips due to very precise requirements in forming multiple layers of a single superconducting material.

It is therefore desirable to create an integrated circuit with superconducting devices capable of operating at a relatively high critical temperature. It is also desirable that such an integrated circuit be relatively easy to manufacture (compared to typical superconducting devices) using conventional chip-making processes and equipment. Other desirable features and characteristics will become apparent from the subsequent detailed description and the appended claims, taken in conjunction with the accompanying drawings and this background discussion.

### BRIEF SUMMARY

According to various exemplary embodiments, an integrated circuit formed on a substrate suitably includes a number of superconducting junctions. Each superconducting junction includes a first superconducting material disposed upon the substrate, an insulating material formed on the first superconducting material, and a second superconducting material formed on the insulating material to create a Josephson junction. The second superconducting material is a different material from the first superconducting material to aid in manufacturability. Any number of electrically conductive interconnects are also provided to interlink the superconducting junctions to thereby form the integrated circuit. Examples of superconducting materials that may be used for the various layers include YBaCu₃O_{7-y} (YBCO) and Bi₂Sr₂CaCu₂O_{y} (Bi2212).

In another exemplary embodiment, a technique for manufacturing a superconducting integrated circuit on a substrate includes the broad steps of forming a first superconducting layer of a first material on the substrate, separating the first superconducting layer into a first portion and a second portion, forming an insulating layer of oxide across the first and second portions, and forming a second superconducting layer of a second material on the insulating layer to thereby form Josephson junctions along the first and second portions of the first superconducting layer, wherein the second material is different from the first material.

### BRIEF DESCRIPTION OF THE DRAWINGS

The present invention will hereinafter be described in conjunction with the following drawing figures, wherein like numerals denote like elements, and

FIG. 1 is a perspective view of an exemplary superconducting device formed upon a substrate;

FIGS. 2(a)-(e) are side views of an exemplary superconducting device during progressive stages of formation;

FIG. 3 is a side view of an exemplary superconducting inverter circuit;

FIG. 4 is a side view of an exemplary superconducting NOR gate circuit; and

FIG. 5 is a side view of an exemplary superconducting device that incorporates multiple superconducting junctions.

### DETAILED DESCRIPTION

The following detailed description of the invention is merely exemplary in nature and is not intended to limit the invention or the application and uses of the invention. Furthermore, there is no intention to be bound by any theory presented in the preceding background of the invention or the following detailed description of the invention.

According to various exemplary embodiments, a superconducting integrated circuit suitably includes one or more Josephson junctions formed with non-identical layers of superconducting material. A first layer may be formed of YBaCu₃O_{7-y} (YBCO) and a second layer may be formed of Bi₂Sr₂CaCu₂O_{y} (Bi2212), for example, to reduce the level of precision needed to etch or otherwise process the various materials on the integrated circuit. In a further embodiment, superconducting devices are formed with multiple Josephson junctions to create Josephson diodes, transistors or other devices. Such devices may be interconnected as appropriate to form various circuits and systems on a common substrate.

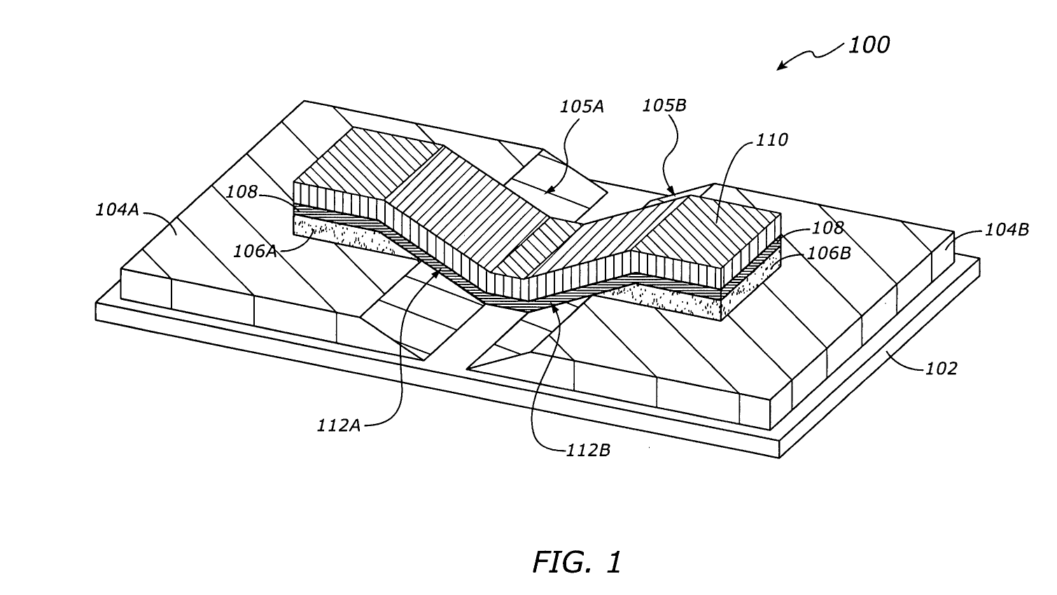

Turning now to the drawing figures and with initial reference to FIG. 1, an exemplary Josephson device 100 formed on a substrate 102 suitably includes a first superconducting layer 104, an insulating layer 106, and a second superconducting material 110 formed from a different material than first superconducting layer 104. An optional barrier layer 108 may also be provided to create one or more Josephson junctions 112A-B between superconducting layers 104 and 110. Each junction 112 is capable of producing an AC and/or DC current under proper conditions such that each superconducting layer 104, 110 suitably acts as a unique electrical node that can be interconnected with other nodes on substrate 102 to create an integrated circuit.

Substrate 102 is any body or base layer onto which other materials may be deposited to form an integrated circuit. Substrate 102 may be formed of any appropriate material used in semiconductor or superconductor circuits including silicon, gallium arsenide, sapphire or any type of glass, plastic, metal or other material. In an exemplary embodiment, substrate 102 is formed from a wafer of strontium tin oxide (SrTiO₃), although other materials could be used in a wide variety of alternate embodiments.

Superconducting layers 104 and 110 are any layers of material capable of exhibiting superconductivity (or near superconductivity) at an appropriate critical temperature for the particular application. Examples of superconducting materials include YBaCu₃O_{7-y} (YBCO), Bi₂Sr₂CaCu₂O_{y} (Bi2212), Tl₂Ba₂CaCu₂O₈ (TBCCO) and the like, as well as many variations of these materials. In one embodiment, layer 104 is formed from YBCO and layer 110 is formed from Bi2212, or vice versa. One example of a discrete superconducting junction 110 made from such materials is described in T. Imaizumi et al., “Tunneling Between Dissimilar High-T_{c} Oxide Superconductors”, PHYSICAL REVIEW LETTERS, vol. 89, no. 1 (1 Jul. 2002), although any other types of junction or junctions could be used in a wide variety of alternate embodiments.

First superconducting layer 104 (also referred to herein as the “lower electrode”) is appropriately placed on substrate 102, as described more fully below. In various embodiments (including the exemplary embodiment shown in FIG. 1), first layer 104 is appropriately split or otherwise divided to create two or more separate portions 104A and 104B. Each of these portions 104A-B forms a unique electrical node and corresponds to at least one Josephson junction 112A-B as appropriate. Although FIG. 1 shows each portion 104A-B as having a ramp edge 105A-B forming the Josephson junction 112A-B, alternate embodiments may be formed to create step-edge junctions, c-axis microbridge junctions, SNS step edge junctions, bicrystal junctions, biepitaxial contacts or the like.

Insulating layer 106 is any layer or other material capable of electrically separating superconducting layers 104 and 110. Accordingly, layer 108 typically exhibits a relatively high electrical resistance. Examples of suitable insulating layers 108 include various oxides, including strontium tin oxide, silicon dioxide or the like. In one embodiment using YBCO and Bi2202 as superconducting materials 104 and 110, respectively, insulating layer 108 may be formed from SrTiO₃.

Optional barrier layer 108 is any material capable of forming a tunneling barrier between superconducting layers 104 and 110. Barrier layer 108 may be formed of any material such as any compound containing praseodymium, lanthanum, strontium, aluminum, tantalum or the like. In an exemplary embodiment using YBCO and Bi2202 as superconducting materials, barrier layer 108 is a layer of PrBa₂Cu₃O_{7-y} (PBCO) that is several nanometers or so in thickness. In various embodiments, however, superconducting layers 104 and 110 may be placed in direct contact with each other, with the natural boundary between the two layers acting as a tunneling barrier, albeit with reduced resistance than would be expected when an artificial barrier layer 108 is present.

Second superconducting layer 110 (also referred to herein as the “upper electrode”) is appropriately formed or placed to create one or more Josephson junctions 112A-B with first superconducting layer 104. As briefly mentioned above, second layer 110 is any material capable of exhibiting superconductivity at the appropriate temperatures for the particular application. Second layer 110 is suitably formed from a different superconducting material than that used for layer 104, however, for ease of manufacturing, as described more fully below. In embodiments wherein first layer 104 is formed from YBCO (T_{c}=93K), for example, second layer 110 may be formed of Bi2202 (T_{c}=110K), TBCCO (T_{c}=125K) or any other appropriate material.

In operation, then, superconducting device 100 acts in an electrical manner similar to a P-N junction commonly found in semiconducting devices, with current flowing across junctions 112A-B in accordance with the DC Josephson effect and/or the AC Josephson effect if a bias voltage is provided between the two superconducting layers 104 and 110. Each layer 104, 110 acts as a distinct electrical node that can be interconnected with other nodes formed on substrate 102 or the like. In further embodiments wherein first layer 104 is split into multiple superconducting portions 104A-B (e.g. as shown in FIG. 1), superconducting device 100 acts as a three-terminal device with each portion 104A-B and second layer 110 each acting as a separate electrical node. These nodes can be electrically biased to create various electrical devices (e.g. diodes, transistors, logic gates and the like) on substrate 102, and interconnected as appropriate.

Alternate embodiments of superconducting device 100 exhibit markedly different structures. As briefly mentioned above, junctions 112 may be formed with any type of physical arrangement (e.g. step edge, microbridge, etc.) in place of the ramp edge 105 arrangement shown in FIG. 1. Similarly, alternate embodiments may not divide first superconducting layer 104 as shown in FIG. 1, but rather may divide layer 104 into any manner of separate portions or may not divide layer 104 at all to thereby support a single Josephson junction 112. Further, the particular junctions 112 may be made with any combination of materials, barrier thicknesses, barrier arrangements and the like in a wide array of equivalent embodiments.

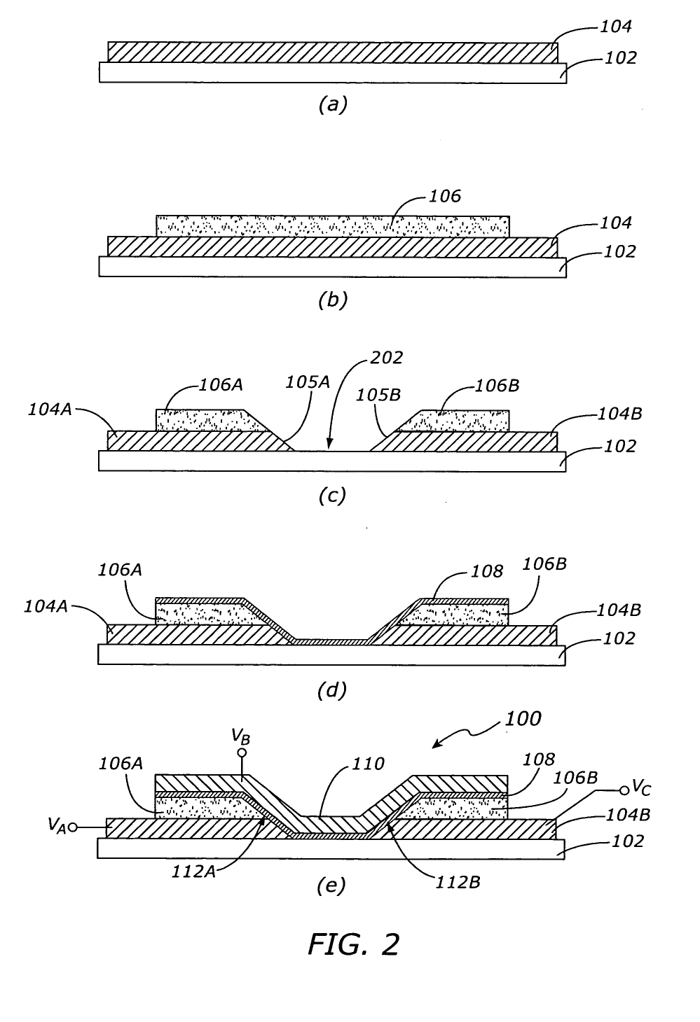

With reference now to FIG. 2, an exemplary process for creating a superconducting device 100 on a substrate 102 suitably includes the broad steps of forming a first superconducting layer 104 (FIG. 2(a)), forming a notch 202 in superconducting layer 104 (FIG. 2(c)), and then forming a second superconducting layer 110 across the notch to create a pair of Josephson junctions (FIG. 2(e)). Additional or alternate steps may also be performed, and the order of the steps described herein may be altered or adjusted such that the various steps are executed in any temporal order. Moreover, the process described in FIGS. 2(a)-(e) focuses on a single device 100 for purposes of simplicity; the concepts and procedures described herein could be readily adapted to integrated circuits having many (e.g. thousands, millions or more) Josephson devices either alone or in combination with conventional semiconducting devices. Indeed, the manufacturing techniques described herein are readily adapted to the large or very large scale integration (VLSI) techniques conventionally used in forming integrated circuits.

Referring now to FIG. 2(a), first superconducting layer 104 is sputtered, deposited or otherwise formed onto substrate 102 as appropriate. In various embodiment, a thin film (e.g. on the order of 250-600 nm or so in thickness) of superconducting material is deposited onto substrate 102 using conventional deposition techniques. A thin film YBCO having a thickness of about 400 nm may be formed on an SrTiO3 substrate, for example, under conditions of about 860 degrees Celsius and 0.2 Torr oxygen pressure, although other embodiments may have widely varying materials, dimensions and conditions.

Insulating layer 106 is then formed on first superconducting layer 104 using any appropriate technique, as shown in FIG. 2(b). As mentioned above, insulating layer 106 may be formed of oxide or another appropriate material, and may have a thickness on the order of 50-200 nm or so. To continue the example from FIG. 2(a), in one embodiment a layer of SrTiO3 having a thickness of about 100 nm or so may be deposited on the YBCO using a pulsed laser, ion beam, radio frequency (RF) or other deposition or sputtering technique.

After the initial layers 104 and 106 are formed on substrate 102, a notch 202 or other gap may be formed through layers 104 and 106 to separate superconducting layer 104 into two portions 104A and 104B separated by an exposed portion of substrate 102, as shown in FIG. 2(c). Notch 202 may be formed using conventional photolithography, or by sawing, milling, etching or otherwise processing the material as appropriate. In one embodiment, notch 202 is formed with argon ion milling. Edges 105A-B of separated portions 104A-B may also be formed to have a ramp or step edge, as desired, for forming Josephson junctions with second superconducting layer 110 as described below.

When the lower superconducting layers 104A-B are appropriately placed and shaped as desired, upper layers of superconducting material 110 and optional barrier material 108 may be formed. Referring to FIG. 2(d), barrier material 108 is sputtered, deposited or otherwise formed into the area exposed by notch 202. In the exemplary embodiment described above, barrier material 108 is a layer of PBCO a few nanometers thick, although other embodiments may use widely varying materials and thicknesses, or may omit barrier material 108 entirely.

The second layer 110 of superconducting material is then deposited or otherwise formed to complete device 100. Layer 110 is any superconducting material such as YBCO or B12202, and may be formed to a thickness of about 100-300 nm or so. Continuing the example above, layer 110 may be formed of about 200 nm of Bi2202 to complement the layer 104 of YBCO previously placed. Again, the particular materials and dimensions may vary widely from embodiment to embodiment.

After the various layers are placed, final milling, etching, lithography or other shaping may be applied to form an upper electrode from layer 110. Referring again to FIG. 1, layer 110 may be formed to a desired width (e.g. on the order of about 40 microns or so) for creating Josephson junctions with layer 104. Because upper electrode 110 and the lower electrodes 104A-B are formed from different materials, conventional photolithographic and other manufacturing techniques may be used to create devices 100, thereby greatly simplifying the production of superconducting devices and circuits.

The entire assembly may then be annealed or otherwise processed (e.g. in an environment of about 800-850 degrees Celsius and about 0.3-0.5 Torr) to create device 100. As mentioned above, the various portions 104A-B of first layer 104 form one or more Josephson junctions with layer 110 along edges 105A-B as appropriate. Each layer 104 and 110 therefore acts as a separate electrical node that can be biased and/or interconnected with other devices and nodes on substrate 102 as appropriate. In various embodiments, devices 100 function similar to P-N junctions that can be readily exploited and combined to form diodes, transistors and other devices.

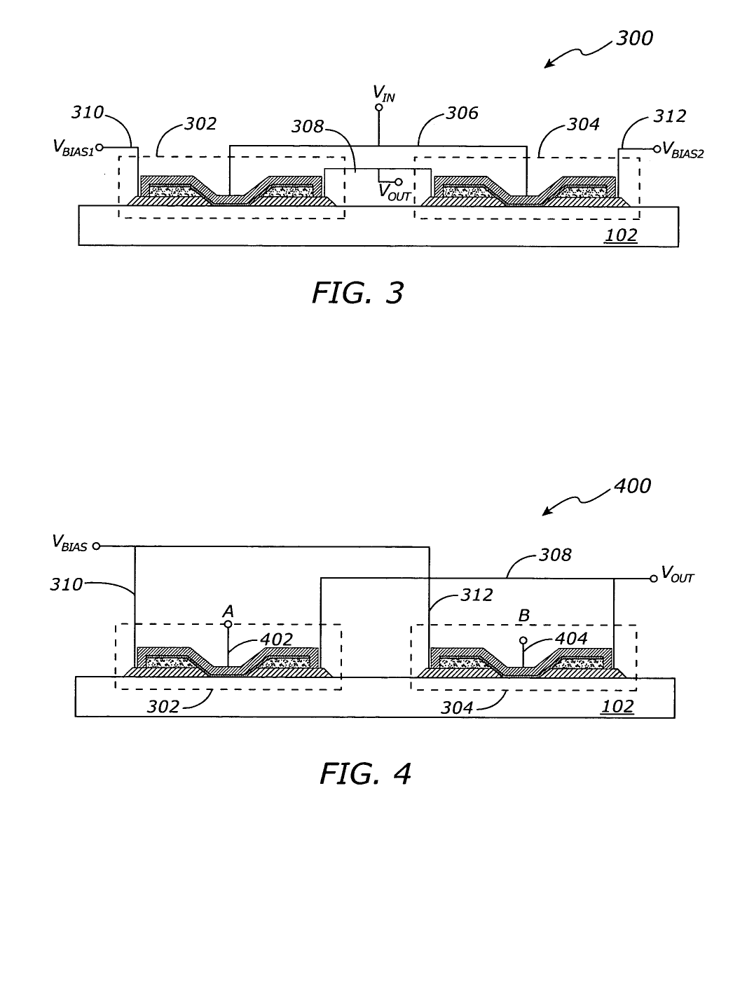

FIGS. 3 and 4 show exemplary circuits that may be formed from Josephson devices 100 as described herein. These and any number of other circuits may be readily formed by applying analogous design techniques used for PN junctions and/or bipolar junction transistors (BJTs) to the Josephson junctions described above. Referring now to FIG. 3, an exemplary digital inverter circuit 300 suitably includes two Josephson devices 302, 304 on a common substrate 102. The upper electrodes of the two devices 302, 304 are electrically coupled to each other via an electrical interconnect 306, and one of the lower electrode portions of device 302 is coupled to a lower electrode portion of device 304 via a second electrical interconnect 308. Interconnect 306 therefore receives an input signal from another component or any other appropriate digital interface, and a logical opposite may be provided at interconnect 308. Optional bias voltages may be applied to devices 302, 304 via interconnects 310 and 312, respectively, to place devices 302, 304 into desired modes of operation. Each of the electrical interconnects 306, 308, 310 and 312 may be any conducting or superconducting material such as copper, aluminum, gold or the like formed on substrate 102 using any conventional technique (e.g. lithography).

Similarly, FIG. 4 shows an exemplary digital NOR gate 400 formed from two Josephson devices 302, 304 as described above using conventional BJT design principles. In the circuit shown in FIG. 4, inputs A and B are provided at the upper electrodes of devices 302, 304, and the logical NOR result from these two inputs is provided from portions of the lower electrodes. A bias voltage may also be provided to place lower electrode at a desired potential with respect to upper electrode 110 to thereby “forward bias” or “reverse bias” the various Josephson junctions and to thereby place devices 302, 304 into desired modes of operation.

Circuits 300, 400 shown in FIGS. 3 and 4 are intended primarily to illustrate that exemplary devices described herein may be interconnected on a substrate 100 to form integrated circuits on a large or very large scale. By properly biasing and interconnecting the various Josephson junctions to exploit the AC and/or DC Josephson effects, digital logic circuits, analog or digital switching circuits, analog amplifiers, voltage and current sources and/or any number of other implementations are possible.

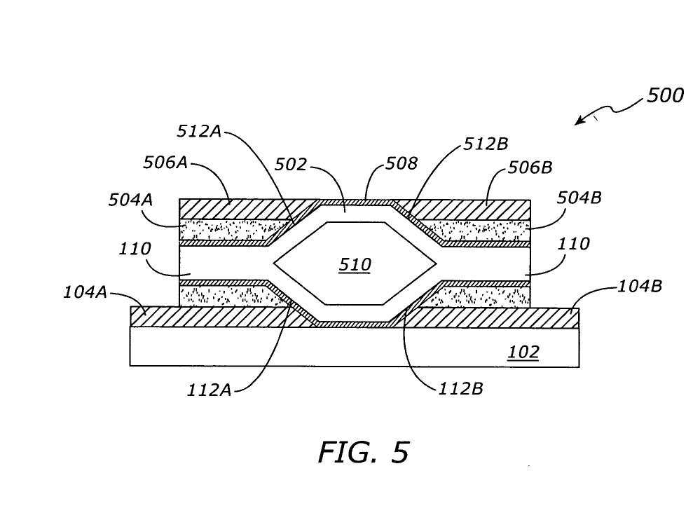

With final reference now to FIG. 5, an alternate device suitably adds a second insulating layer 504, a third superconducting layer 506 and an optional second barrier layer 508 to device 100 (FIG. 1) to create a Josephson device 500 with four distinct Josephson barriers. Third superconducting layer 506 is appropriately formed of a superconducting material different from that of layer 110; layers 506 and 104, however, may be formed from a common material such as YBCO.

To create device 500, upper electrode 110 as described above in conjunction with FIG. 2(e) is placed in electrical contact with an upper layer 506 of superconducting material as appropriate. To this end, layer 110 may be formed or shaped using conventional deposition, lithography and/or other techniques as described above to form a single electrical node with layer 502, which is appropriately formed of the same material as layer 110, and may be formed around a filling material 510. Filler material 510 may be any spacing material such as an insulating oxide or the like. Alternatively, layer 110 may be formed and shaped to encompass both layer 110 and layer 502, and gap 510 may be omitted. Insulating layer 504 and third superconducting layer 506 are then formed on layer 110/502 using deposition, sputtering or other appropriate techniques. In various embodiments, milling or shaping of the uppermost electrode (corresponding to third layer 506) can be combined with the formation of the electrode corresponding to layer 110, thereby further simplifying the manufacturing process.

In operation, layer 506 forms a third electrical node that interacts with node 110/502 through Josephson junctions 512A-B. Device 508 suitably functions in a manner similar to a bipolar junction transistor, with node 110/502 roughly correlating to a base terminal and nodes 506 and 104 acting as emitter and/or collector. Accordingly, the general techniques and principles described herein may be readily modified to create a wide array of superconducting devices, including devices that function as diodes, transistors or the like.

Although various devices and circuits illustrated herein are frequently described with respect to a dual-junction device with a split first semiconducting layer, the concepts of dissimilar superconducting layers may be applied to any superconducting device or circuit. Equivalent embodiments to those described herein may include any number of Josephson junctions, for example, or may incorporate any combinations of superconducting, insulating and other materials.

While at least one exemplary embodiment has been presented in the foregoing detailed description, it should be appreciated that a vast number of equivalent variations exist. It should also be appreciated that the exemplary embodiments described herein are only examples, and are not intended to limit the scope, applicability, or configuration of the invention in any way. Rather, the foregoing detailed description will provide those skilled in the art with a convenient road map for implementing an exemplary embodiment of the invention. Accordingly, various changes may be made in the function, arrangement and order of elements and process steps without departing from the scope of the invention as set forth in the appended claims and their legal equivalents.

1. An integrated circuit formed on a substrate, the integrated circuit comprising:
a plurality of superconducting junctions, wherein each superconducting junction comprises a first superconducting material disposed upon the substrate, an insulating material formed on the first superconducting material, and a second superconducting material formed on the insulating material to create a Josephson junction, wherein the second superconducting material is different from the first superconducting material; and
a plurality of electrically conductive interconnects coupling the plurality of superconducting junctions to each other to thereby form the integrated circuit.

2. The integrated circuit of claim 1 wherein the first superconducting material is YBaCu₃O_{7-y} (YBCO).

3. The integrated circuit of claim 2 wherein the second superconducting material is Bi₂Sr₂CaCu₂O_{y} (Bi2212).

4. The integrated circuit of claim 1 wherein the first superconducting material is Bi₂Sr₂CaCu₂O_{y} (Bi2212).

5. The integrated circuit of claim 4 wherein the second superconducting material is YBaCu₃O_{7-y} (YBCO).

6. The integrated circuit of claim 1 wherein the first superconducting material comprises a ramp edge.

7. The integrated circuit of claim 6 wherein the Josephson junction is formed along the ramp edge.

8. The integrated circuit of claim 1 further comprising a barrier layer separating the first and second superconducting materials.

9. An integrated circuit formed on a substrate, the integrated circuit having a plurality of superconducting junctions, wherein each superconducting junction comprises:
a first superconducting layer of YBaCu₃O_{7-y} (YBCO) disposed upon the substrate and having a ramp edge;
an insulating layer comprising an oxide formed on at least the ramp edge of the first superconducting material; and
a second superconducting layer of Bi₂Sr₂CaCu₂O_{y} (Bi2212) formed on the insulating material to create a Josephson junction.

10. A superconducting device formed on a substrate, the device comprising:
a first superconducting layer of a first superconducting material disposed on the substrate, wherein the first superconducting layer comprises a first portion and a second portion separated by a notch formed through the first superconducting layer to thereby expose at least a portion of the substrate;
an insulating layer disposed upon the first and second portions of first superconducting layer as well as the exposed portion of the substrate; and
a second superconducting layer of a second superconducting material different from the first superconducting material disposed on the insulating layer to thereby form Josephson junctions with the first and second portions of the first superconducting layers.

11. The integrated circuit of claim 10 wherein the first superconducting material is YBaCu₃O_{7-y} (YBCO).

12. The integrated circuit of claim 11 wherein the second superconducting material is Bi₂Sr₂CaCu₂O_{y} (Bi2212).

13. The integrated circuit of claim 12 wherein the first portion of the first superconducting layer, the second portion of the superconducting layer and the insulating layer from three distinct electrical nodes.

14. A method of forming a superconducting integrated circuit on a substrate, the method comprising the steps of:
forming a first superconducting layer of a first material on the substrate;
forming an insulating layer of oxide across the first superconducting layer; and
forming a notch in the first superconducting layer to thereby separate the first superconducting layer into a first portion and a second portion;
forming a second superconducting layer of a second material on the insulating layer to thereby form Josephson junctions along the first and second portions of the first superconducting layer, wherein the second material is different from the first material.

15. The integrated circuit of claim 14 wherein the first superconducting material is YBaCu₃O_{7-y} (YBCO).

16. The integrated circuit of claim 15 wherein the second superconducting material is Bi₂Sr₂CaCu₂O_{y} (Bi2212).

17. A method of forming a superconducting integrated circuit on a substrate, the method comprising the steps of:
forming a first superconducting layer of YBaCu₃O_{7-y} (YBCO) on the substrate;
forming an insulating layer on the first superconducting material;
forming a notch in the first superconducting layer and the insulating layer to thereby separate the first superconducting layer into a first portion and a second portion separated by an exposed portion of the substrate, each of the first and second portions having a ramp edge;
forming a barrier layer across the spacing layer, ramp edges of the first and second portions, and the exposed portion of the substrate; and
forming a second superconducting layer of Bi₂Sr₂CaCu₂O_{y} (Bi2212) on the barrier layer to thereby form Josephson junctions along the ramp edges of the first and second portions of the first superconducting layer.

18. A superconducting device formed on a substrate, the device comprising:
a first superconducting layer formed of a first material on the substrate;
a first insulating layer formed on the first superconducting layer;
a second superconducting layer formed of a second material on the first insulating layer to thereby form a Josephson junction with the first superconducting layer;
a second insulating layer formed on the second superconducting layer; and
a third superconducting layer formed of the first material on the second superconducting layer, wherein a second Josephson junction is formed between the second superconducting layer and the third superconducting layer.

19. The integrated circuit of claim 18 wherein the first material is YBaCu₃O_{7-y} (YBCO).

20. The integrated circuit of claim 19 wherein the second material is Bi₂Sr₂CaCu₂O_{y} (Bi2212).
